(19) United States
(12) Patent Application Publication
(10) Pub. No.: US 2021/0384342 A1
(43) Pub. Date: Dec. 9, 2021

(54) SEMICONDUCTOR DEVICE AND MANUFACTURING METHOD THEREOF

(71) Applicant: INNOSCIENCE (ZHUHAI) TECHNOLOGY CO., LTD., Zuuhai City (CN)

(72) Inventors: WEIGANG YAO, ZHUHAI CITY (CN); ANBANG ZHANG, ZHUHAI CITY (CN)

(21) Appl. No.: 16/960,563

(22) PCT Filed: Jun. 4, 2020
(86) PCT No.: PCT/CN2020/094414

§ 371 Date: Jul. 8, 2020

(51) Int. Cl. H01L 29/778; H01L 29/20; H01L 29/66

(52) U.S. Cl. CPC H01L 29/7787; H01L 29/66462; H01L 29/2003

(57) ABSTRACT

Some embodiments of the disclosure provide a semiconductor device. The semiconductor device includes: a substrate having a first side and a second side opposite the first side; a first nitride semiconductor layer disposed on the first side of the substrate; a second nitride semiconductor layer on the first nitride semiconductor layer and having a band gap greater than a band gap of the first nitride semiconductor layer; a first electrode disposed on the second nitride semiconductor layer; a second electrode disposed on the second nitride semiconductor layer; a first semiconductor structure formed adjacent to the second side of the substrate; and a second semiconductor structure formed adjacent to the second side of the substrate; and wherein the first semiconductor structure and the second semiconductor structure are adjacent to each other.

### TECHNICAL FIELD

The disclosure relates to a semiconductor device, and in particular, to a semiconductor device with integrated high-electron-mobility transistor(s) (HEMT) and diode(s).

### BACKGROUND

A semiconductor component including a direct band gap, for example, a semiconductor component including a group III-V material or group III-V compounds, may operate or work under a variety of conditions or environments (for example, different voltages or frequencies) due to its characteristics.

The foregoing semiconductor component may include a HEMT, a heterojunction bipolar transistor (HBT), a heterojunction field effect transistor (HFET), or a modulation-doped field effect transistor (MODFET).

### SUMMARY OF THE INVENTION

Some embodiments of the disclosure provide a semiconductor device. The semiconductor device includes: a substrate having a first side and a second side opposite the first side; a first nitride semiconductor layer disposed on the first side of the substrate; a second nitride semiconductor layer on the first nitride semiconductor layer and having a band gap greater than a band gap of the first nitride semiconductor layer; a first electrode disposed on the second nitride semiconductor layer; a second electrode disposed on the second nitride semiconductor layer; a first semiconductor structure formed adjacent to the second side of the substrate; and a second semiconductor structure formed adjacent to the second side of the substrate; and wherein the first semiconductor structure and the second semiconductor structure are adjacent to each other.

Some embodiments of the disclosure provide a method for manufacturing a semiconductor device. The method includes: providing a substrate; forming a first nitride semiconductor layer on a first side of the substrate; forming a second nitride semiconductor layer on the first nitride semiconductor layer; forming a first electrode and a second electrode on the second nitride semiconductor layer; and forming a first semiconductor structure and a second semiconductor structure at a second side of the substrate, and wherein the second side is opposite to the first side.

### BRIEF DESCRIPTION OF THE DRAWINGS

Aspects of the disclosure will become more comprehensible from the following detailed description made with reference to the accompanying drawings. It should be noted that, various features may not be drawn to scale. In fact, the sizes of the various features may be increased or reduced arbitrarily for the purpose of clear description.

FIG. 1A is a side view of a semiconductor device according to some embodiments of the disclosure;

FIG. 1B is a side view of a semiconductor device according to some embodiments of the disclosure;

FIG. 2 is a schematic diagram of an equivalent circuit of a semiconductor device of FIG. 1A or FIG. 1B according to some embodiments of the disclosure; and

FIG. 3A, FIG. 3B, FIG. 3C, FIG. 3D, FIG. 3E, and FIG. 3F show several operations for manufacturing a semiconductor device according to some embodiments of the disclosure.

### PREFERRED EMBODIMENT OF THE PRESENT INVENTION

The following disclosure provides many different embodiments or examples for implementing different features of the provided subject matter. Specific examples of components and arrangements are described below. Certainly, these descriptions are merely examples and are not intended to be limiting. In the disclosure, in the following descriptions, the description of the first feature being formed on or above the second feature may include an embodiment in which the first feature and the second feature are formed to be in direct contact, and may further include an embodiment in which an additional feature may be formed between the first feature and the second feature to enable the first feature and the second feature to be not in direct contact. In addition, in the disclosure, reference numerals and/or letters may be repeated in examples. This repetition is for the purpose of simplification and clarity, and does not indicate a relationship between the described various embodiments and/or configurations.

The embodiments of the disclosure are described in detail below. However, it should be understood that many applicable concepts provided by the disclosure may be implemented in a plurality of specific environments. The described specific embodiments are only illustrative and do not limit the scope of the disclosure.

The present disclosure provides a semiconductor device including a high-electron-mobility transistor (HEMT) and a diode disposed on opposite sides of the substrate. The high-electron-mobility transistor (HEMT) and the diode may be connected by a through silicon via (TSV) technique. Then, a wafer level chip size package (WLCSP) technique may be used for electroplating solder balls on the HEMT side or on the diode side.

The present semiconductor device may reduce parasitic inductance and parasitic resistance of the device compared to the conventional arts. As a result, the present semiconductor device may improve an operation speed of a switch of the device and reduce the loss of the power. In addition, a reduced volume of the packaged semiconductor device can be obtained, which provides the advantage of better system design. Overall, the present semiconductor device may have a better efficiency compared the conventional arts. The semiconductor device of the present disclosure can be applied in, but is not limited to, diodes, high electron mobility transistor devices (HEMT devices) and the other suitable electronic components.

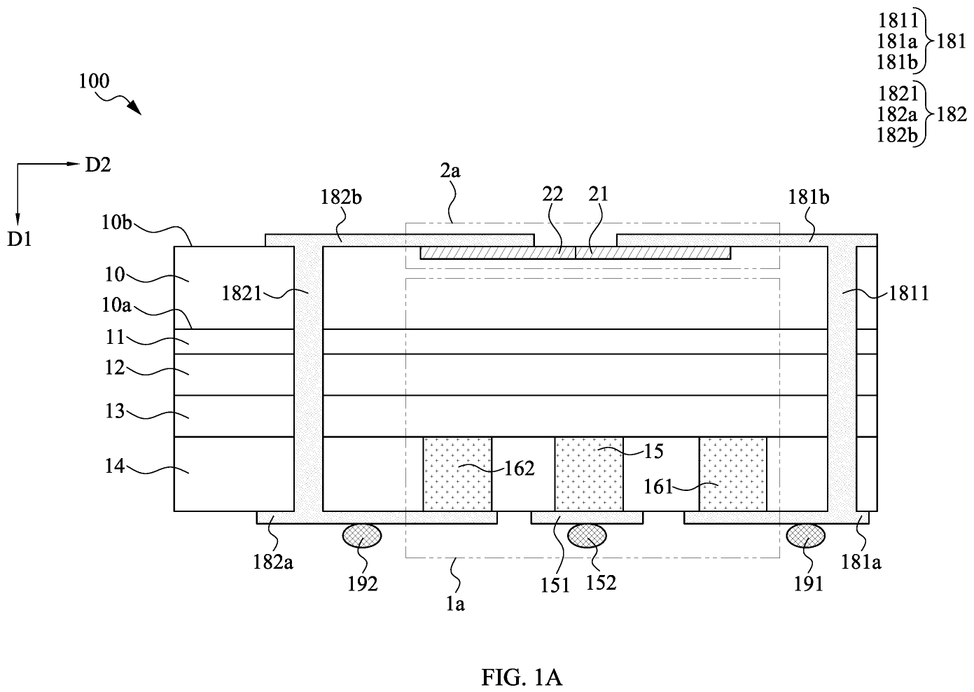

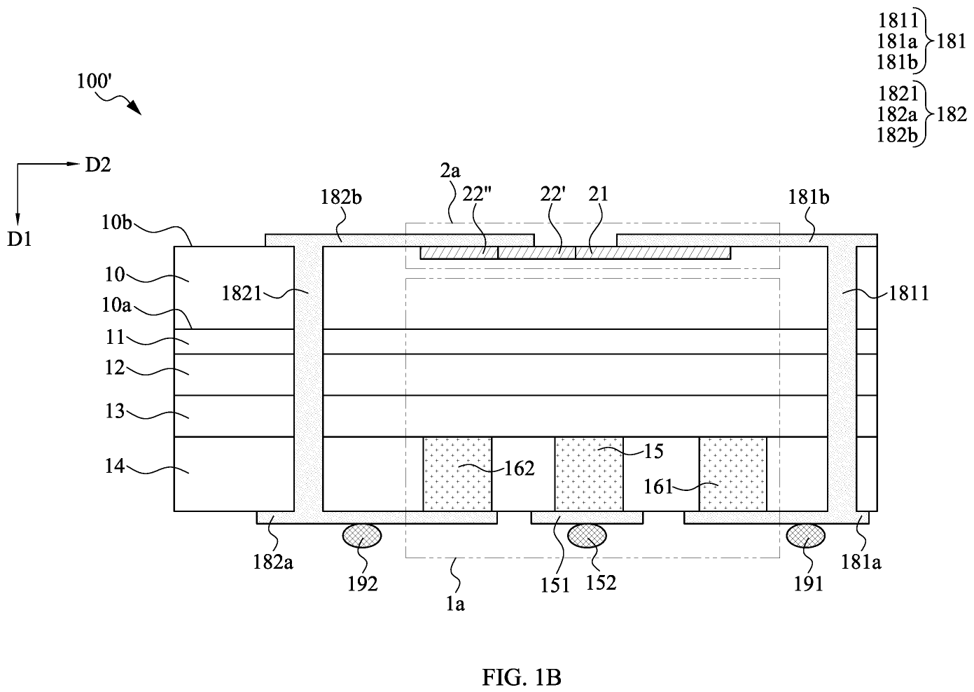

FIG. 1A is a side view of a semiconductor device according to some embodiments of the disclosure.

Referring to FIG. 1A, the semiconductor device 100 may include a component 1a and a component 2a.

The component 1a may include a substrate 10, a buffer layer 11, a semiconductor layer 12, a semiconductor layer 13, a passivation layer 14, a conductive structure 15, a conductive structure 151, a conductive structure 161, a conductive structure 162, a conductive structure 181a, and a conductive structure 182a.

The substrate 10 may include, for example, but is not limited to, silicon (Si), doped silicon (doped Si) or another semiconductor material. In some embodiments, the substrate 10 may include intrinsic semiconductor material. In some embodiments, the substrate 10 may include intrinsic silicon. In some embodiments, the substrate 10 may include a p-type semiconductor material. The substrate 10 may include a p-type semiconductor material having a doping concentration of about 10¹⁷ cm⁻³ to about 10²¹ cm⁻³. The substrate 10 may include a p-type semiconductor material having a doping concentration of about 10¹⁹ cm⁻³ to about 10²¹ cm⁻³. The substrate 10 may include a p-type semiconductor material having a doping concentration of about 10²⁰ cm⁻³ to about 10²¹ cm⁻³. In some embodiments, the substrate 10 may include a p-type doped silicon layer. In some embodiments, the substrate 10 may include a silicon layer doped with boron (B). In some embodiments, the substrate 10 may include a silicon layer doped with gallium (Ga). In some embodiments, the substrate 10 may include an n-type semiconductor material. The substrate 10 may include an n-type semiconductor material having a doping concentration of about 10¹⁷ cm⁻³ to about 10²¹ cm⁻³. The substrate 10 may include an n-type semiconductor material having a doping concentration of about 10¹⁹ cm⁻³ to about 10²¹ cm⁻³. The substrate 10 may include an n-type semiconductor material having a doping concentration of about 10²⁰ cm⁻³ to about 10²¹ cm⁻³. In some embodiments, the substrate 10 may include an n-type doped silicon layer. In some embodiments, the substrate 10 may include a silicon layer doped with arsenic (As). In some embodiments, the substrate 10 may include a silicon layer doped with phosphorus (P).

In some embodiments, the substrate 10 may have a thickness approximately between 1.0 mm and 2.0 mm. The substrate 10 may have a thickness approximately 1.5 mm. In some embodiments, a thinning process may be applied to the substrate 10 and the substrate 10 may be thinned to have a thickness less than 5000 μm. In some embodiments, after the thinning process, the substrate 10 of the semiconductor device 100 may have a thickness approximately between 50 and 500 μm. In some embodiments, after the thinning process, the substrate 10 of the semiconductor device 100 may have a thickness approximately between 100 and 400 μm. After the thinning process, the substrate 10 may have the advantage of dissipating the heat more efficiently and thus improve the device performance.

The buffer layer 11 may be disposed on the substrate 10. The buffer layer 11 may be disposed on a first side 10a of the substrate 10. In some embodiments, the buffer layer 11 may include nitrides. In some embodiments, the buffer layer 11 may include, for example, but is not limited to, aluminum nitride (AlN). In some embodiments, the buffer layer 11 may include, for example, but is not limited to, aluminum gallium nitride (AlGaN). The buffer layer 11 may include a multilayer structure. The buffer layer 11 may include a single layer structure.

The semiconductor layer 12 may be disposed on the first side 10a the substrate 10. The semiconductor layer 12 may be disposed on the buffer layer 11. The semiconductor layer 12 may include a group III-V material. The semiconductor layer 12 may include, for example, but is not limited to, group III nitride. The semiconductor layer 12 may include, for example, but is not limited to, GaN. The semiconductor layer 12 may include, for example, but is not limited to, AlN. The semiconductor layer 12 may include, for example, but is not limited to, InN. The semiconductor layer 12 may include, for example, but is not limited to, compound InₓAl_{y}Ga_{1-x-y}N, where x+y [symbol] 1. The semiconductor layer 12 may include, for example, but is not limited to, compound Al_{y}Ga_{(1-y)}N, where y [symbol] 1.

The semiconductor layer 13 may be disposed on the semiconductor layer 12. The semiconductor layer 13 may include a group III-V material. The semiconductor layer 13 may include, for example, but is not limited to, group III nitride. The semiconductor layer 13 may include, for example, but is not limited to, compound Al_{y}Ga_{(1-y)}N, where y [symbol] 1. The semiconductor layer 13 may include, for example, but is not limited to, GaN. The semiconductor layer 13 may include, for example, but is not limited to, AlN. The semiconductor layer 13 may include, for example, but is not limited to, InN. The semiconductor layer 13 may include, for example, but is not limited to, compound InₓAl_{y}Ga_{1-x-y}N, where x+y [symbol] 1.

A heterojunction may be formed between the semiconductor layer 13 and the semiconductor layer 12. The semiconductor layer 13 may have a greater band gap than the semiconductor layer 12. For example, the semiconductor layer 13 may include AlGaN that may have a band gap of about 4.0 eV, and the semiconductor layer 12 may include GaN that may have a band gap of about 3.4 eV.

In the component 1a, the semiconductor layer 12 may be used as a channel layer. In the component 1a, the semiconductor layer 12 may be used as a channel layer disposed on the buffer layer 11. In the component 1a, because the band gap of the semiconductor layer 12 is less than the band gap of the semiconductor layer 13, two dimensional electron gas (2DEG) may be formed in the semiconductor layer 12. In the component 1a, because the band gap of the semiconductor layer 12 is less than the band gap of the semiconductor layer 13, 2DEG may be formed in the semiconductor layer 12 and the 2DEG is close to interfaces of the semiconductor layer 13 and the semiconductor layer 12.

In the component 1a, the semiconductor layer 13 may be used as a barrier layer. In the component 1a, the semiconductor layer 13 may be used as a barrier layer disposed on the semiconductor layer 12.

A doped semiconductor layer (not shown in the figure) may be disposed between the semiconductor layer 13 and the conductive structure 15. The doped semiconductor layer may include a doped group III-V material. The doped semiconductor layer may include a p-type group III-V material. The doped semiconductor layer may include, for example, but is not limited to, p-type group III nitride. The doped semiconductor layer may include, for example, but is not limited to, p-type GaN. The doped semiconductor layer may include, for example, but is not limited to, p-type AlN. The doped semiconductor layer may include, for example, but is not limited to, p-type InN. The doped semiconductor layer may include, for example, but is not limited to, p-type AlGaN. The doped semiconductor layer may include, for example, but is not limited to, p-type InGaN. The doped semiconductor layer may include, for example, but is not limited to, p-type InAlN. If the doped semiconductor layer includes a p-type group III-V material, a doped material of the doped semiconductor layer may include, for example, but is not limited to, at least one of Mg, Zn, and Ca.

The doped semiconductor layer may also include another p-type semiconductor material. The doped semiconductor layer may include, for example, but is not limited to, p-type CuO. The doped semiconductor layer may include, for example, but is not limited to, p-type NiOₓ. If the doped semiconductor layer includes p-type CuO, a doped material of the doped semiconductor layer may include, for example, but is not limited to, at least one of Mg, Zn, and Ca. If the doped semiconductor layer includes p-type NiOₓ, a doped material of the doped semiconductor layer may include, for example, but is not limited to, at least one of Mg, Zn, and Ca.

The doped semiconductor layer may include a p-type semiconductor material having a doping concentration of about 10¹⁷ cm⁻³ to about 10²¹ cm⁻³. The doped semiconductor layer may include a p-type semiconductor material having a doping concentration of about 10¹⁹ cm⁻³ to about 10²¹ cm⁻³. The doped semiconductor layer may include a p-type semiconductor material having a doping concentration of about 10²⁰ cm⁻³ to about 10²¹ cm⁻³.

The conductive structure 15 may be disposed on the semiconductor layer 13. The conductive structure 15 may be disposed on the doped semiconductor layer (not shown in the figure), so that the doped semiconductor layer is located between the semiconductor layer 13 and the conductive structure 15.

The conductive structure 15 may include a metal. The conductive structure 15 may include, for example, but is not limited to, gold (Au), platinum (Pt), titanium (Ti), palladium (Pd), nickel (Ni), and tungsten (W). The conductive structure 15 may include a metal compound. The conductive structure 15 may include, for example, but is not limited to, titanium nitride (TiN).

In the component 1a, the conductive structure 15 may be used as a gate conductor. In the component 1a, the conductive structure 15 may be configured to control the 2DEG in the semiconductor layer 12. In the component 1a, a voltage may be applied to the conductive structure 15 to control the 2DEG in the semiconductor layer 12. In the component 1a, a voltage may be applied to the conductive structure 15 to control the 2DEG in the semiconductor layer 12 and below the conductive structure 15. In the component 1a, a voltage may be applied to the conductive structure 15 to control the connection or disconnection between the conductive structure 161 and the conductive structure 162.

The conductive structure 161 may be disposed on the semiconductor layer 13. The conductive structure 161 may include a metal. The conductive structure 162 may be disposed on the semiconductor layer 13. The conductive structure 162 may include a metal.

In some embodiments, the element of the conductive structure 161 or the conductive structure 162 may be selected from a group, for example, but is not limited to, including titanium (Ti), tantalum (Ta), tungsten (W), aluminum (Al), cobalt (Co), copper (Cu), nickel (Ni), gold (Au), platinum (Pt), lead (Pb), and molybdenum (Mo) or the compounds thereof.

In the component 1a, the conductive structure 161 may be used as, for example, but is not limited to, a source conductor. In the component 1a, the conductive structure 161 may be used as, for example, but is not limited to, a drain conductor.

In the component 1a, the conductive structure 162 may be used as, for example, but is not limited to, a drain conductor. In the component 1a, the conductive structure 162 may be used as, for example, but is not limited to, a source conductor.

In some embodiments, the conductive structure 161 may be used as a source conductor (i.e., source electrode) of the component 1a, the conductive structure 162 may be used as a drain conductor (i.e., drain electrode) of the component 1a, and the conductive structure 15 may be used as a gate conductor (i.e., gate electrode) of the component 1a. Although the conductive structure 161 that may be used as a source conductor and the conductive structure 162 that may be used as a drain conductor are respectively disposed on both sides of the conductive structure 15 that may be used as a gate conductor in FIG. 1A, the conductive structure 161, the conductive structure 162, and the conductive structure 15 may be disposed differently in other embodiments of the disclosure according to design requirements.

The conductive structure 181a may be located on the semiconductor layer 13. The conductive structure 181a may be disposed on the conductive structure 161. The conductive structure 181a may be used for electrically connecting the conductive structure 161 to the outside. The conductive structure 181a may include a metal. The conductive structure 181a may include a metal compound. The conductive structure 181a may include, for example, but is not limited to, copper (Cu), tungsten carbide (WC), titanium (Ti), titanium nitride (TiN) or aluminum copper (Al—Cu).

The conductive structure 182a may be located on the semiconductor layer 13. The conductive structure 182a may be disposed on the conductive structure 162. The conductive structure 182a may be used for electrically connecting the conductive structure 162 to the outside. The conductive structure 182a may include a metal. The conductive structure 182a may include a metal compound. The conductive structure 182a may include, for example, but is not limited to, copper (Cu), tungsten carbide (WC), titanium (Ti), titanium nitride (TiN) or aluminum copper (Al—Cu).

The conductive structure 151 may be located on the semiconductor layer 13. The conductive structure 151 may be disposed on the conductive structure 15. The conductive structure 151 may be used for electrically connecting the conductive structure 15 to the outside. The conductive structure 151 may include a metal. The conductive structure 151 may include a metal compound. The conductive structure 151 may include, for example, but is not limited to, copper (Cu), tungsten carbide (WC), titanium (Ti), titanium nitride (TiN) or aluminum copper (Al—Cu).

The passivation layer 14 may be disposed on the semiconductor layer 13. The passivation layer 14 may be used as an interlayer dielectric layer. The passivation layer 14 may surround the conductive structure 161. The passivation layer 14 may surround the conductive structure 162. The passivation layer 14 may surround the conductive structure 15. The passivation layer 14 may surround the doped semiconductor layer (not shown in the figure). The passivation layer 14 may include a dielectric material. The passivation layer 14 may include nitride. The passivation layer 14 may include, for example, but is not limited to, silicon nitride (Si₃N₄). The passivation layer 14 may include oxide. The passivation layer 14 may include, for example, but is not limited to, silicon oxide (SiO₂). The passivation layer 14 may electrically isolate the conductive structure 161 from the conductive structure 162. The passivation layer 14 may electrically isolate the conductive structure 161 from the conductive structure 15. The passivation layer 14 may electrically isolate the conductive structure 162 from the conductive structure 15.

Also referring to FIG. 1A, the component 2a may include a substrate 10, a semiconductor structure 21, a semiconductor structure 22, a conductive structure 181b, and a conductive structure 182b. In some embodiments, the component 2a may further include a capacitor, a resistor, and/or an inductor.

The substrate 10 may include, for example, but is not limited to, silicon (Si), doped silicon (doped Si) or another semiconductor material. In some embodiments, the substrate 10 may include intrinsic semiconductor material. In some embodiments, the substrate 10 may include intrinsic silicon. In some embodiments, the substrate 10 may include a p-type semiconductor material. The substrate 10 may include a p-type semiconductor material having a doping concentration of about 10¹⁷ cm⁻³ to about 10²¹ cm⁻³. The substrate 10 may include a p-type semiconductor material having a doping concentration of about 10¹⁹ cm⁻³ to about 10²¹ cm⁻³. The substrate 10 may include a p-type semiconductor material having a doping concentration of about 10²⁰ cm⁻³ to about 10²¹ cm⁻³. In some embodiments, the substrate 10 may include a p-type doped silicon layer. In some embodiments, the substrate 10 may include a silicon layer doped with boron (B). In some embodiments, the substrate 10 may include a silicon layer doped with gallium (Ga). In some embodiments, the substrate 10 may include an n-type semiconductor material. The substrate 10 may include an n-type semiconductor material having a doping concentration of about 10¹⁷ cm⁻³ to about 10²¹ cm⁻³. The substrate 10 may include an n-type semiconductor material having a doping concentration of about 10¹⁹ cm⁻³ to about 10²¹ cm⁻³. The substrate 10 may include an n-type semiconductor material having a doping concentration of about 10²⁰ cm⁻³ to about 10²¹ cm⁻³. In some embodiments, the substrate 10 may include an n-type doped silicon layer. In some embodiments, the substrate 10 may include a silicon layer doped with arsenic (As). In some embodiments, the substrate 10 may include a silicon layer doped with phosphorus (P).

The substrate 10 may be shared by the component 1a and the component 2a. The component 1a and the component 2a may be disposed on the substrate 10. The component 1a and the component 2a may be disposed on the single substrate 10. The component 1a and the component 2a may be disposed on opposite sides of the substrate 10. For example, the component 1a may be formed on a side 10a of the substrate 10 and the component 2a may be formed on a side 10b of the substrate 10, wherein the side 10b is opposite to the side 10a.

The semiconductor structure 21 may be disposed in the substrate 10. The semiconductor structure 21 may be built in the substrate 10. The semiconductor structure 21 may be embedded in the substrate 10. The semiconductor structure 21 may be disposed in the substrate 10 and is formed at a second side 10b, which is opposite to the first side 10a, of the substrate 10.

The semiconductor structure 21 may be formed in the substrate 10 by doping a p-type semiconductor material. The semiconductor structure 21 may include at least one of boron (B) and gallium (Ga). The semiconductor structure 21 may include a p-type material and the semiconductor structure 22 may by undoped. The semiconductor structure 21 may be doped with a conductive type material and the semiconductor structure 22 may be doped with another conductive type material.

In some embodiments, the semiconductor structure 21 may have a p-type semiconductor material with a doping concentration of about 10¹² cm⁻³ to about 10¹⁹ cm⁻³. In some embodiments, the semiconductor structure 21 may have a p-type semiconductor material with a doping concentration of about 10¹³ cm⁻³ to about 10¹⁸ cm⁻³. In some embodiments, the semiconductor structure 21 may have a p-type semiconductor material with a doping concentration of about 10¹⁶ cm⁻³.

The semiconductor structure 21 may be formed in the substrate 10 by doping an n-type semiconductor material. The semiconductor structure 21 may include at least one of phosphorus (P) and arsenic (As). The semiconductor structure 21 may include an n-type material and the semiconductor structure 22 may by undoped.

In some embodiments, the semiconductor structure 21 may have an n-type semiconductor material with a doping concentration of about 10¹² cm⁻³ to about 10¹⁹ cm⁻³. In some embodiments, the semiconductor structure 21 may have an n-type semiconductor material with a doping concentration of about 10¹³ cm⁻³ to about 10¹⁸ cm⁻³. In some embodiments, the semiconductor structure 21 may have an n-type semiconductor material with a doping concentration of about 10¹⁶ cm⁻³.

The semiconductor structure 21 and the substrate 10 may have different polarities. It should be noted that, if the substrate 10 is an n-type semiconductor and the semiconductor structure 21 is a p-type semiconductor, the semiconductor structure 21 and the substrate 10 may be regarded as having different polarities. It should be noted that, if the substrate 10 is a p-type semiconductor and the semiconductor structure 21 is an n-type semiconductor, the semiconductor structure 21 and the substrate 10 may be regarded as having different polarities. It should be noted that, if the substrate 10 is an undoped semiconductor (for example, intrinsic silicon) and the semiconductor structure 21 is an n-type semiconductor, the semiconductor structure 21 and the substrate 10 may be regarded as having different polarities. It should be noted that, if the substrate 10 is an undoped semiconductor (for example, intrinsic silicon) and the semiconductor structure 21 is a p-type semiconductor, the semiconductor structure 21 and the substrate 10 may be regarded as having different polarities. It should be noted that, if a concentration of an n-type dopant is greater than a concentration of a p-type dopant in the substrate 10, and a concentration of a p-type dopant is greater than a concentration of an n-type dopant in the semiconductor structure 21, the semiconductor structure 21 and the substrate 10 may be regarded as having different polarities. It should be noted that, if a concentration of a p-type dopant is greater than a concentration of an n-type dopant in the substrate 10, and a concentration of an n-type dopant is greater than a concentration of a p-type dopant in the semiconductor structure 21, the semiconductor structure 21 and the substrate 10 may be regarded as having different polarities.

The semiconductor structure 21 may have a depth approximately between 1000-10000 nm in the D1 direction. The semiconductor structure 21 may have a depth approximately between 3000-8000 nm in the D1 direction. The semiconductor structure 21 may have a depth approximately between 5000-7000 nm in the D1 direction. The semiconductor structure 21 may have a thickness approximately between 1000-10000 nm in the D1 direction. The semiconductor structure 21 may have a thickness approximately between 3000-8000 nm in the D1 direction. The semiconductor structure 21 may have a thickness approximately between 5000-7000 nm in the D1 direction.

The semiconductor structure 22 may be disposed in the substrate 10. The semiconductor structure 22 may be built in the substrate 10. The semiconductor structure 22 may be embedded in the substrate 10. The semiconductor structure 22 may be disposed in the substrate 10 and formed at a second side 10b, which is opposite to the first side 10a, of the substrate 10.

The semiconductor structure 22 may be formed in the substrate 10 by doping an n-type semiconductor material. The semiconductor structure 22 may include at least one of phosphorus (P) and arsenic (As). The semiconductor structure 22 may include an n-type material and the semiconductor structure 21 may by undoped. The semiconductor structure 22 may be doped with a conductive type material and the semiconductor structure 21 may be doped with another conductive type material.

In some embodiments, the semiconductor structure 22 may have an n-type semiconductor material with a doping concentration of about 10¹² cm⁻³ to about 10¹⁹ cm⁻³. In some embodiments, the semiconductor structure 22 may have an n-type semiconductor material with a doping concentration of about 10¹³ cm⁻³ to about 10¹⁸ cm⁻³. In some embodiments, the semiconductor structure 22 may have an n-type semiconductor material with a doping concentration of about 10¹⁶ cm⁻³.

The semiconductor structure 22 may be formed in the substrate 10 by doping a p-type semiconductor material. The semiconductor structure 22 may include at least one of boron (B) and gallium (Ga). The semiconductor structure 22 may include a p-type material and the semiconductor structure 21 may by undoped.

In some embodiments, the semiconductor structure 22 may have a p-type semiconductor material with a doping concentration of about 10¹² cm⁻³ to about 10¹⁹ cm⁻³. In some embodiments, the semiconductor structure 22 may have a p-type semiconductor material with a doping concentration of about 10¹³ cm⁻³ to about 10¹⁸ cm⁻³. In some embodiments, the semiconductor structure 22 may have a p-type semiconductor material with a doping concentration of about 10¹⁶ cm⁻³.

The semiconductor structure 22 and the substrate 10 may have different polarities. It should be noted that, if the substrate 10 is a p-type semiconductor and the semiconductor structure 22 is an n-type semiconductor, the semiconductor structure 22 and the substrate 10 may be regarded as having different polarities. It should be noted that, if the substrate 10 is an n-type semiconductor and the semiconductor structure 22 is a p-type semiconductor, the semiconductor structure 22 and the substrate 10 may be regarded as having different polarities. It should be noted that, if the substrate 10 is an undoped semiconductor (for example, intrinsic silicon) and the semiconductor structure 22 is an n-type semiconductor, the semiconductor structure 22 and the substrate 10 may be regarded as having different polarities. It should be noted that, if the substrate 10 is an undoped semiconductor (for example, intrinsic silicon) and the semiconductor structure 22 is a p-type semiconductor, the semiconductor structure 22 and the substrate 10 may be regarded as having different polarities. It should be noted that, if a concentration of a p-type dopant is greater than a concentration of an n-type dopant in the substrate 10, and a concentration of an n-type dopant is greater than a concentration of a p-type dopant in the semiconductor structure 22, the semiconductor structure 22 and the substrate 10 may be regarded as having different polarities. It should be noted that, if a concentration of an n-type dopant is greater than a concentration of a p-type dopant in the substrate 10, and a concentration of a p-type dopant is greater than a concentration of an n-type dopant in the semiconductor structure 22, the semiconductor structure 22 and the substrate 10 may be regarded as having different polarities.

The semiconductor structure 22 may have a depth approximately between 1000-10000 nm in the D1 direction. The semiconductor structure 22 may have a depth approximately between 3000-8000 nm in the D1 direction. The semiconductor structure 22 may have a depth approximately between 5000-7000 nm in the D1 direction. The semiconductor structure 22 may have a thickness approximately between 1000-10000 nm in the D1 direction. The semiconductor structure 22 may have a thickness approximately between 3000-8000 nm in the D1 direction. The semiconductor structure 22 may have a thickness approximately between 5000-7000 nm in the D1 direction.

The semiconductor structure 21 may be adjacent to the semiconductor structure 22. The semiconductor structure 21 may be laterally adjacent to the semiconductor structure 22. The semiconductor structure 21 may be horizontally adjacent to the semiconductor structure 22. The semiconductor structure 21 may be transversely adjacent to the semiconductor structure 22. The semiconductor structure 21 may have an elevation substantially identical to the semiconductor structure 22. The semiconductor structure 21 may be in direct contact with the semiconductor structure 22.

In some embodiments, the semiconductor structures 21 and 22 may have equal lengths in the D2 direction. In some embodiments, the semiconductor structures 21 and 22 may have different lengths in the D2 direction.

In some embodiments, the semiconductor structure 21 and the semiconductor structure 22 may form a diode. For example, the semiconductor structure 21 may include a p-type semiconductor material and the semiconductor structure 22 may include an n-type semiconductor material so that a p-n junction diode is formed. For example, the semiconductor structure 21 may include an n-type semiconductor material and the semiconductor structure 22 may include a p-type semiconductor material so that a p-n junction is formed.

The conductive structure 181b may be disposed on the semiconductor structure 21. The conductive structure 181b may be used as an ohmic contact electrically connected to the semiconductor structure 21. The conductive structure 181b may include a metal. The conductive structure 181b may include, for example, but is not limited to, titanium (Ti). The conductive structure 181b may include a metal compound. The conductive structure 181b may include, for example, but is not limited to, copper (Cu), tungsten carbide (WC), titanium (Ti), titanium nitride (TiN) or aluminum copper (Al—Cu). The conductive structure 181b may be formed, for example, but is not limited to, by electroplating.

The conductive structure 182b may be disposed on the semiconductor structure 22. The conductive structure 182b may be used as an ohmic contact electrically connected to the semiconductor structure 22. The conductive structure 182b may include a metal. The conductive structure 182b may include, for example, but is not limited to, titanium (Ti). The conductive structure 182b may include a metal compound. The conductive structure 182b may include, for example, but is not limited to, copper (Cu), tungsten carbide (WC), titanium (Ti), titanium nitride (TiN) or aluminum copper (Al—Cu). The conductive structure 182b may be formed, for example, but is not limited to, by electroplating.

The conductive structure 181a and the conductive structure 181b may be connected to each other by an elongated portion 1811. The elongated portion 1811 may include a through substrate via (TSV). The conductive structures 181a and 181b and the elongated portion 1811 are collectively referred to an interconnect structure 181. That is, the interconnect structure 181 includes the elongated portion 1811 connecting the conductive structures 181a and 181b. The interconnect structure 181 may pass through the substrate 10, the buffer layer 11, the semiconductor layer 12, the semiconductor layer 13, and the passivation layer 14. The interconnect structure 181 may include the conductive structure 181a connected to the conductive structure 161 and the conductive structure 181b connected to the semiconductor structure 21.

The conductive structure 182a and the conductive structure 182b may be connected to each other by an elongated portion 1821. The elongated portion 1821 may include a through substrate via (TSV). The conductive structures 182a and 182b and the elongated portion 1821 are collectively referred to an interconnect structure 182. That is, the interconnect structure 182 includes the elongated portion 1821 connecting the conductive structures 182a and 182b. The interconnect structure 182 may pass through the substrate 10, the buffer layer 11, the semiconductor layer 12, the semiconductor layer 13, and the passivation layer 14. The interconnect structure 182 may include the conductive structure 182a connected to the conductive structure 162 and the conductive structure 182b connected to the semiconductor structure 22.

In some embodiments, the semiconductor structure 21 may be electrically connected to the conductive structure 161 and the semiconductor structure 22 may be electrically connected to the conductive structure 162. In some embodiments, the semiconductor structure 21 may be electrically connected to the conductive structure 161 via the interconnect structure 181 and the semiconductor structure 22 may be electrically connected to the conductive structure 162 via the interconnect structure 182.

In some embodiments, a solder material 152 may be formed on the conductive structure 151. In some embodiments, the solder material 152 may include a metal. In some embodiments, the element of the solder material 152 may be selected from a group comprising tin (Sn), silver (Ag), copper (Cu), zinc (Zn), and indium (In) or the compound thereof.

In some embodiments, a solder material 191 may be formed on the conductive structure 181a. In some embodiments, the solder material 191 may include a metal. In some embodiments, the element of the solder material 191 may be selected from a group comprising tin (Sn), silver (Ag), copper (Cu), zinc (Zn), and indium (In) or the compound thereof.

In some embodiments, a solder material 192 may be formed on the conductive structure 182a. In some embodiments, the solder material 192 may include a metal. In some embodiments, the element of the solder material 192 may be selected from a group comprising tin (Sn), silver (Ag), copper (Cu), zinc (Zn), and indium (In) or the compound thereof.

In some embodiments, the component 1a and the component 2a may be built in the same substrate 10. The component 1a and the component 2a may be disposed on the same substrate 10. The component 1a and the component 2a may share the same substrate 10. The component 1a and the component 2a may dispose on opposite sides of the substrate 10. The component 1a and the component 2a may share the interconnect structures 181 and 182.

FIG. 1B is a side view of a semiconductor device according to some embodiments of the disclosure.

The semiconductor component 100′ shown in FIG. 1B is similar to the semiconductor component 100 shown in FIG. 1A, and the difference lies in that the semiconductor structure 22 in FIG. 1A is replaced by a semiconductor structure 22′ and a semiconductor structure 22″ in FIG. 1B. In other words, the component 2a may include three or more semiconductor structures. In FIG. 1B, the component 2a may include a semiconductor structure 21, a semiconductor structure 22′, and a semiconductor structure 22″.

As shown in FIG. 1B, the component 2a may include a substrate 10, a semiconductor structure 21, a semiconductor structure 22′, a semiconductor structure 22″, a conductive structure 181b, and a conductive structure 182b.

In some embodiments, the semiconductor structure 21 may include a p-type semiconductor material, the semiconductor structure 22′ may include a lightly-doped n-type semiconductor material (i.e., n⁻ semiconductor material), and the semiconductor structure 22″ may include a heavily doped n-type semiconductor material (i.e., n⁺ semiconductor material). In some embodiments, the semiconductor structure 21, the semiconductor structure 22′ and the semiconductor structure 22″ may form a diode. For example, the semiconductor structure 21 may include a p-type semiconductor material and the semiconductor structures 22′ and 22″ may include an n-type semiconductor material so that a p-n junction diode is formed.

In some embodiments, the semiconductor structure 21 may include an n-type semiconductor material, the semiconductor structure 22′ may include a lightly-doped p-type semiconductor material (i.e., p⁻ semiconductor material), and the semiconductor structure 22″ may include a heavily doped p-type semiconductor material (i.e., p⁺ semiconductor material). In some embodiments, the semiconductor structure 21, the semiconductor structure 22′ and the semiconductor structure 22″ may form a diode. For example, the semiconductor structure 21 may include an n-type semiconductor material and the semiconductor structures 22′ and 22″ may include a p-type semiconductor material so that a p-n junction diode is formed.

In some embodiments, the conductive structure 181b may be disposed on the semiconductor structure 21 and the conductive structure 182b may be disposed on the semiconductor structure 22″.

In some embodiments, the semiconductor structures 21, 22, and 22″ may have equal lengths in the D2 direction. In some embodiments, the semiconductor structures 21, 22, and 22″ may have different lengths in the D2 direction.

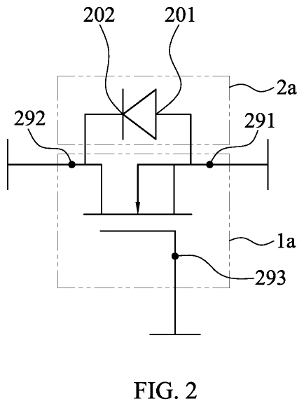

FIG. 2 is a view of an equivalent circuit of a semiconductor device of FIG. 1A or FIG. 1B according to some embodiments of the disclosure.

The component 1a may include a contact 291, a contact 292, and a contact 293. The component 1a may include the contact 291, the contact 292, and the contact 293 of a semiconductor device. The component 1a may include the contact 291, the contact 292, and the contact 293 of an HEMT. In some embodiments, the contact 291 may be used as a source contact of the HEMT, the contact 292 may be used as a drain contact of the HEMT, and the contact 293 may be used as a gate contact of the HEMT.

The component 2a may include an anode 201 and a cathode 202. The component 2a may include the anode 201 and the cathode 202 of a semiconductor device. The component 2a may include the anode 201 and the cathode 202 of a diode. The component 2a may include the anode 201 and the cathode 202 of a p-n junction diode.

In some embodiments, the contact 291 may connect to the anode 201 and the contact 292 may connect to the cathode 202. In some embodiments, the contact 291 may electrically connect to the anode 201 and the contact 292 may electrically connect to the cathode 202. In some embodiments, the contact 291 of the HEMT which is used as a source contact may electrically connect to the anode 201 of the p-n junction diode and the contact 292 of the HEMT which is used as a drain contact may electrically connect to the cathode 202 of the p-n junction diode. In some embodiments, the contact 291 of the HEMT which is used as a source contact may electrically connect to the anode 201 of the p-n junction diode via the interconnect structure 181 shown in FIG. 1A or FIG. 1B and the contact 292 of the HEMT which is used as a drain contact may electrically connect to the cathode 202 of the p-n junction diode via the interconnect structure 182 shown in FIG. 1A or FIG. 1B.

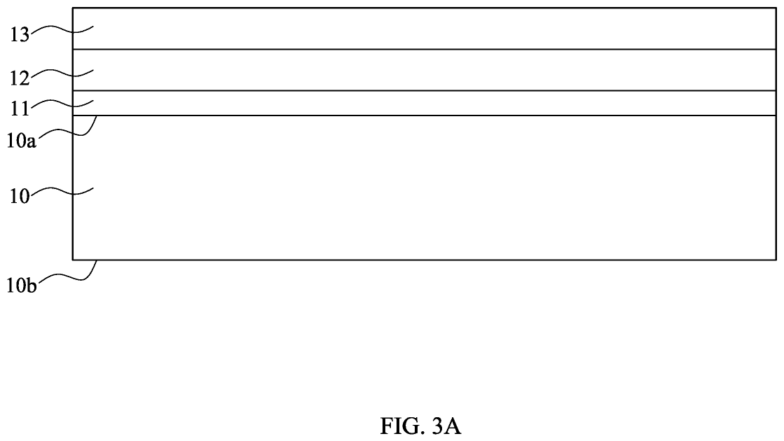

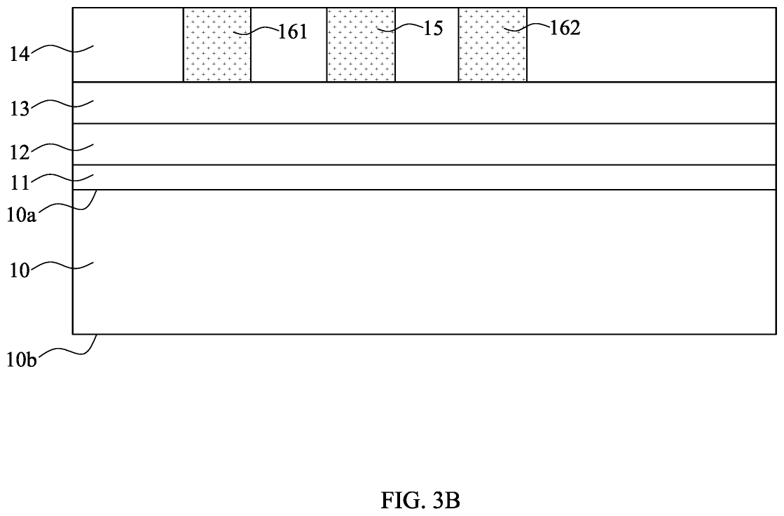

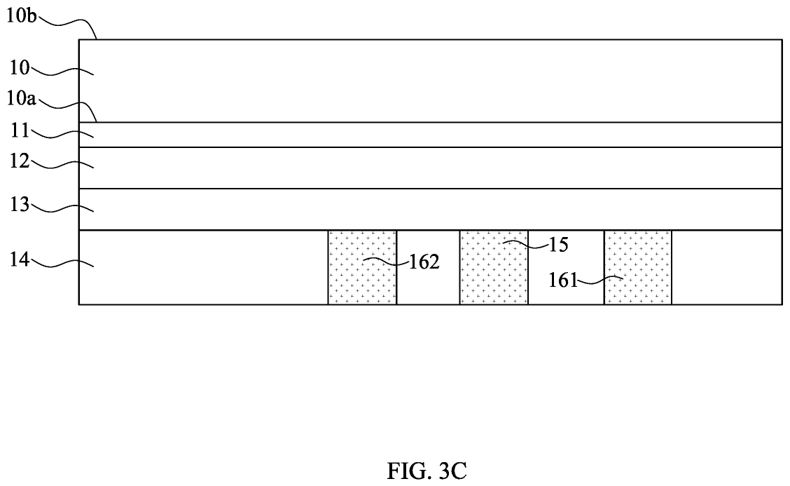

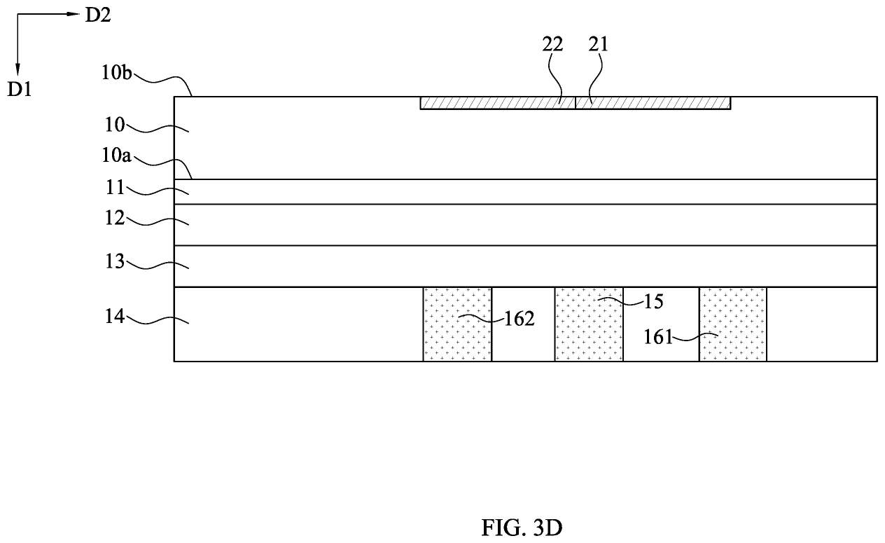

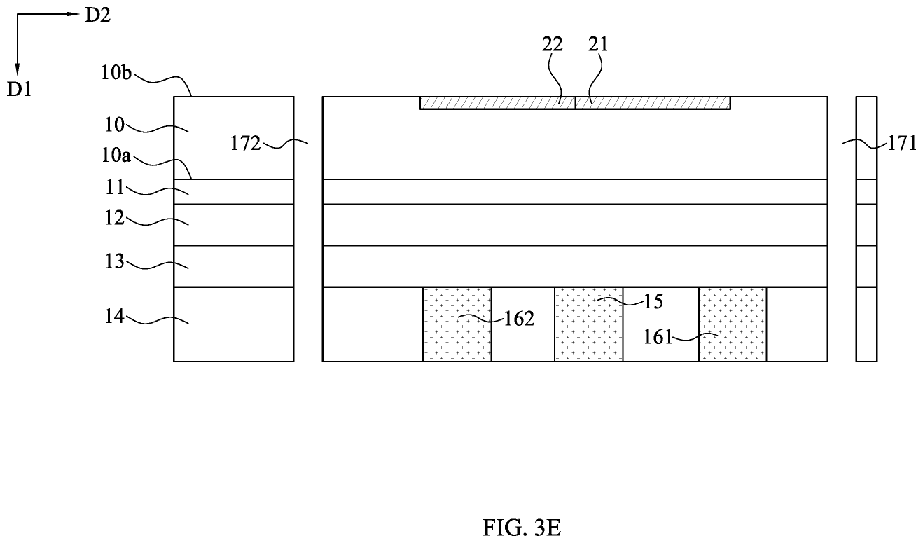

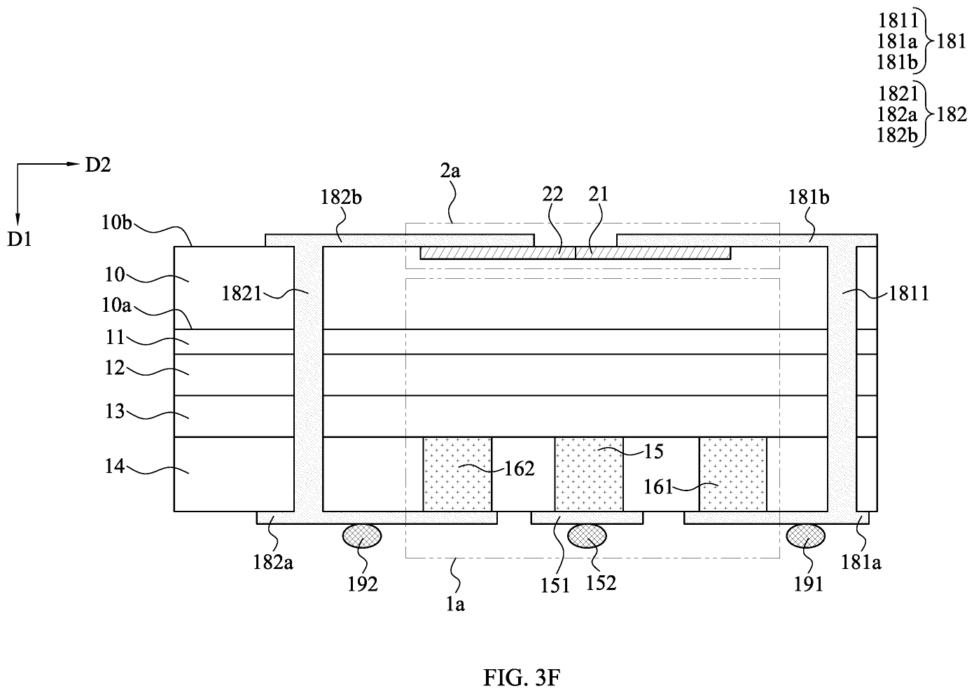

FIG. 3A, FIG. 3B, FIG. 3C, FIG. 3D, FIG. 3E, and FIG. 3F show several operations for manufacturing a semiconductor device according to some embodiments of the disclosure. FIG. 3A, FIG. 3B, FIG. 3C, FIG. 3D, FIG. 3E, and FIG. 3F depict several operations for manufacturing the semiconductor device 100 shown in FIG. 1A.

Referring to FIG. 3A, a substrate 10 is provided. The substrate 10 has two opposite sides 10a and 10b. In some embodiments, the substrate 10 may include a silicon substrate. In some embodiments, the substrate 10 may include an intrinsic semiconductor material. In some embodiments, the substrate 10 may include intrinsic silicon. In some embodiments, the substrate 10 may be doped with a dopant. In some embodiments, the substrate 10 may include a p-type semiconductor material. In some embodiments, the substrate 10 may be doped with at least one of boron (B) and gallium (Ga) to form a p-type semiconductor material. In some embodiments, the substrate 10 may include an n-type semiconductor material. In some embodiments, the substrate 10 may be doped with at least one of phosphorus (P) and arsenic (As) to form an n-type semiconductor material.

In some embodiments, a buffer layer 11 is formed on the substrate 10. In some embodiments, the buffer layer 11 is formed on the side 10a of the substrate 10. In some embodiments, the buffer layer 11 may be formed through chemical vapor deposition (CVD) and/or another suitable deposition step. In some embodiments, the buffer layer 11 may be formed on the substrate 10 through CVD and/or another suitable deposition step.

In some embodiments, a semiconductor layer 12 is formed on the buffer layer 11. In some embodiments, the semiconductor layer 12 is formed on the side 10a of the substrate 10. In some embodiments, the semiconductor layer 12 may be formed through CVD and/or another suitable deposition step. In some embodiments, the semiconductor layer 12 may be formed on the buffer layer 11 through CVD and/or another suitable deposition step.

In some embodiments, a semiconductor layer 13 is formed on the semiconductor layer 12. In some embodiments, the semiconductor layer 13 is formed on the semiconductor layer 12 on the side 10a of the substrate 10. In some embodiments, the semiconductor layer 13 may be formed through CVD and/or another suitable deposition step. In some embodiments, the semiconductor layer 13 may be formed on the semiconductor layer 12 through CVD and/or another suitable deposition step. It should be noted that, the semiconductor layer 13 may be formed after the semiconductor layer 12. It should be noted that, a heterojunction may be formed when the semiconductor layer 13 is disposed on the semiconductor layer 12. It should be noted that, a band gap of the formed semiconductor layer 13 may be greater than a band gap of the formed semiconductor layer 12. It should be noted that, due to the polarization phenomenon of the formed heterojunction between the semiconductor layer 13 and the semiconductor layer 12, 2DEG may be formed in the semiconductor layer 12 having a smaller band gap. It should be noted that, due to the polarization phenomenon of the formed heterojunction between the semiconductor layer 13 and the semiconductor layer 12, in the semiconductor layer 12 having a smaller band gap, 2DEG may be formed close to an interface between the semiconductor layer 12 and the semiconductor layer 13.

Referring to FIG. 3B, the passivation layer 14 may be formed on the semiconductor layer 13. The passivation layer 14 may be formed on the semiconductor layer 13 and encircle the conductive structures 15, 161 and 162. The passivation layer 14 may be formed on the semiconductor layer 13 and surround the conductive structures 15, 161 and 162. The passivation layer 14 may be formed through a deposition step. In some embodiments, the passivation layer 14 may be formed on the semiconductor layer 13 through CVD and/or another suitable deposition step. In some embodiments, the passivation layer 14 may be formed on the semiconductor layer 13 through CVD and/or another suitable deposition step.

The conductive structure 161 may be formed on the semiconductor layer 13. The conductive structure 161 may be formed on the semiconductor layer 13 and encircled by the passivation layer 14. The conductive structure 161 may be formed on the semiconductor layer 13 and surrounded by the passivation layer 14. In some embodiments, the conductive structure 161 may be formed through a deposition step. In some embodiments, the conductive structure 161 may be formed on the semiconductor layer 13. In some embodiments, the conductive structure 161 may be formed on the semiconductor layer 13 through CVD and/or another suitable deposition step.

The conductive structure 162 may be formed on the semiconductor layer 13. The conductive structure 162 may be formed on the semiconductor layer 13 and encircled by the passivation layer 14. The conductive structure 162 may be formed on the semiconductor layer 13 and surrounded by the passivation layer 14. In some embodiments, the conductive structure 162 may be formed through a deposition step. In some embodiments, the conductive structure 162 may be formed on the semiconductor layer 13. In some embodiments, the conductive structure 162 may be formed on the semiconductor layer 13 through CVD and/or another suitable deposition step.

The conductive structure 15 may be formed on the semiconductor layer 13. The conductive structure 15 may be formed on the semiconductor layer 13 and encircled by the passivation layer 14. The conductive structure 15 may be formed on the semiconductor layer 13 and surrounded by the passivation layer 14. In some embodiments, the conductive structure 15 may be formed through a deposition step. In some embodiments, the conductive structure 15 may be formed through a deposition step. In some embodiments, the conductive structure 15 may be formed through CVD and/or another suitable deposition step. In some embodiments, the conductive structure 15 may be formed on the semiconductor layer 13 through CVD and/or another suitable deposition step. In some embodiments, the conductive structure 15 may be formed on a doped semiconductor layer (not shown in FIG. 3B) above the semiconductor layer 13 through CVD and/or another suitable deposition step.

Referring to FIG. 3C, after the conductive structure 161, the conductive structure 162, and the conductive structure 15, and the passivation layer 14 are formed on the semiconductor layer 13, the device in the manufacturing may be flipped over to facilitate the manufacturing operations on the side 10b, opposite to the side 10a, of the substrate 10.

In addition, in some embodiments, a thinning process may be performed on the side 10b of the substrate 10. In some embodiments, the thinning process may be applied by polishing, grinding, etching, a combination thereof, or other suitable techniques to form a thinned substrate 10.

In some embodiments, the substrate 10 may have a thickness approximately between 1.0 mm and 2.0 mm. The substrate 10 may have a thickness approximately 1.5 mm. In some embodiments, a thinning process may be applied to the substrate 10 so that the substrate 10 may have a thickness less than 5000 μm. In some embodiments, after the thinning process, the substrate 10 may have a thickness approximately between 50 and 500 μm. In some embodiments, after the thinning process, the substrate 10 may have a thickness approximately between 100 and 400 μm. After the thinning process, the substrate 10 may have the advantage of dissipating the heat more efficiently and thus improve the device performance.

In some embodiments, the substrate 10 may have a thickness which is reduced from a range approximately between 1.0 mm and 2.0 mm to less than 5000 μm. In some embodiments, the substrate 10 may have a thickness which is reduced from approximately 1.5 mm to a range approximately between 50 μm and 500 μm.

Referring to FIG. 3D, the semiconductor structure 21 and the semiconductor structure 22 are formed at the side 10b, opposite to the side 10a, of the substrate 10.

In some embodiments, the semiconductor structure 21 may include a p-type semiconductor material. In some embodiments, the semiconductor structure 21 may include a p-type semiconductor material by doping at least one of boron (B) and gallium (Ga). In some embodiments, the semiconductor structure 21 may be doped with a p-type semiconductor material to have a doping concentration of about 10¹² cm⁻³ to about 10¹⁹ cm⁻³. In some embodiments, the semiconductor structure 21 may be doped with a p-type semiconductor material to have a doping concentration of about 10¹³ cm⁻³ to about 10¹⁸ cm⁻³. In some embodiments, the semiconductor structure 21 may be doped with a p-type semiconductor material to have a doping concentration of about 10¹⁶ cm⁻³.

In some embodiments, the semiconductor structure 21 may include an n-type semiconductor material. In some embodiments, the semiconductor structure 21 may include an n-type semiconductor material by doping at least one of phosphorus (P) and arsenic (As). In some embodiments, the semiconductor structure 21 may be doped with an n-type semiconductor material to have a doping concentration of about 10¹² cm⁻³ to about 10¹⁹ cm⁻³. In some embodiments, the semiconductor structure 21 may be doped with an n-type semiconductor material to have a doping concentration of about 10¹³ cm⁻³ to about 10¹⁸ cm⁻³. In some embodiments, the semiconductor structure 21 may be doped with an n-type semiconductor material to have a doping concentration of about 10¹⁶ cm⁻³.

In some embodiments, the semiconductor structure 21 may be undoped.

In some embodiments, the semiconductor structure 22 may include an n-type semiconductor material. In some embodiments, the semiconductor structure 22 may include an n-type semiconductor material by doping at least one of phosphorus (P) and arsenic (As). In some embodiments, the semiconductor structure 22 may be doped with an n-type semiconductor material to have a doping concentration of about 10¹² cm⁻³ to about 10¹⁹ cm⁻³. In some embodiments, the semiconductor structure 22 may be doped with an n-type semiconductor material to have a doping concentration of about 10¹³ cm⁻³ to about 10¹⁸ cm⁻³. In some embodiments, the semiconductor structure 22 may be doped with an n-type semiconductor material to have a doping concentration of about 10¹⁶ cm⁻³.

In some embodiments, the semiconductor structure 22 may include a p-type semiconductor material. In some embodiments, the semiconductor structure 22 may include a p-type semiconductor material by doping at least one of boron (B) and gallium (Ga). In some embodiments, the semiconductor structure 22 may be doped with a p-type semiconductor material to have a doping concentration of about 10¹² cm⁻³ to about 10¹⁹ cm⁻³. In some embodiments, the semiconductor structure 22 may be doped with a p-type semiconductor material to have a doping concentration of about 10¹³ cm⁻³ to about 10¹⁸ cm⁻³. In some embodiments, the semiconductor structure 22 may be doped with a p-type semiconductor material to have a doping concentration of about 10¹⁶ cm⁻³.

In some embodiments, the semiconductor structure 22 may be undoped.

In some embodiments, if the semiconductor structure 21 includes the p-type semiconductor material and the semiconductor structure 22 includes the n-type semiconductor materials, the semiconductor structures 21 and 22 may form a p-n junction diode, the semiconductor structure 21 may be used as an anode of the p-n junction diode and the semiconductor structure 22 may be used as a cathode of the p-n junction diode.

In some embodiments, the semiconductor structures 21 and 22 may have equal lengths in the D2 direction. In some embodiments, the semiconductor structures 21 and 22 may have different lengths in the D2 direction.

Referring to FIG. 3E, via holes 171 and 172 may be formed by removing a portion of the substrate 10, the buffer layer 11, the semiconductor layer 12, the semiconductor layer 13, and the passivation layer 14. In some embodiments, via holes 171 and 172 may be formed by removing a portion of the substrate 10, the buffer layer 11, the semiconductor layer 12, the semiconductor layer 13, and the passivation layer 14 by the TSV technique.

Referring to FIG. 3F, an interconnect structure 181 may be formed by filling the via hole 171 as shown in FIG. 3E and an interconnect structure 182 may be formed by filling the via hole 172 as shown in FIG. 3E. The via holes 171 and 172 shown in FIG. 3E are filled with conductive materials to form elongated portions 1811 and 1812. In some embodiments, the elongated portions 1811 and 1812 may pass through the substrate 10, the buffer layer 11, the semiconductor layer 12, the semiconductor layer 13, and the passivation layer 14. In some embodiments, the elongated portions 1811 and 1812 may penetrate through the substrate 10, the buffer layer 11, the semiconductor layer 12, the semiconductor layer 13, and the passivation layer 14.

In some embodiments, the conductive structure 181a may be formed on the passivation layer 14. The conductive structure 181a may be formed on the conductive structure 161. The conductive structure 181a may be used for electrically connecting the conductive structure 161 to the outside. The conductive structure 181a may be used for electrically connecting the conductive structure 161 to the elongated portion 1811. In some embodiments, the conductive structure 181a may be formed on the passivation layer 14 through CVD and/or another suitable deposition step. In some embodiments, the conductive structure 181a may be formed on the conductive structure 161 through CVD and/or another suitable deposition step.

In some embodiments, the conductive structure 182a may be formed on the passivation layer 14. The conductive structure 182a may be formed on the conductive structure 162. The conductive structure 182a may be used for electrically connecting the conductive structure 162 to the outside. The conductive structure 182a may be used for electrically connecting the conductive structure 162 to the elongated portion 1821. In some embodiments, the conductive structure 182a may be formed on the passivation layer 14 through CVD and/or another suitable deposition step. In some embodiments, the conductive structure 182a may be formed on the conductive structure 162 through CVD and/or another suitable deposition step.

In some embodiments, the conductive structure 181b may be formed on the semiconductor structure 21. In some embodiments, the conductive structure 181b may be formed on the substrate 10. In some embodiments, the conductive structure 181b may be formed on the side 10b of the substrate 10. The conductive structure 181b may be used for electrically connecting to the semiconductor structure 21 to the outside. The conductive structure 181a may be used for electrically connecting the semiconductor structure 21 to the elongated portion 1811. In some embodiments, the conductive structure 181b may be formed on the semiconductor structure 21 through CVD and/or another suitable deposition step. In some embodiments, the conductive structure 181b may be formed on the substrate 10 through CVD and/or another suitable deposition step.

In some embodiments, the conductive structure 182b may be formed on the semiconductor structure 22. In some embodiments, the conductive structure 182b may be formed on the substrate 10. In some embodiments, the conductive structure 182b may be formed on the side 10b of the substrate 10. The conductive structure 182b may be used for electrically connecting to the semiconductor structure 22 to the outside. The conductive structure 182b may be used for electrically connecting the semiconductor structure 22 to the elongated portion 1821. In some embodiments, the conductive structure 182b may be formed on the semiconductor structure 22 through CVD and/or another suitable deposition step. In some embodiments, the conductive structure 182b may be formed on the substrate 10 through CVD and/or another suitable deposition step.

In some embodiments, a solder material 191 may be formed on the interconnect structure 181 and a solder material 192 may be formed on the interconnect structure 182. In some embodiments, a solder material 191 may be formed on the conductive structure 181a and a solder material 192 may be formed on the conductive structure 182a.

Referring to FIG. 3F again, a component 1a may be formed to include a substrate 10, a buffer layer 11, a semiconductor layer 12, a semiconductor layer 13, a passivation layer 14, a conductive structure 15, a conductive structure 151, a conductive structure 161, a conductive structure 162, a conductive structure 181a, and a conductive structure 182a. A component 2a may be formed to include a substrate 10, a semiconductor structure 21, a semiconductor structure 22, a conductive structure 181b, and a conductive structure 182b.

The component 1a may include a transistor. The component 1a may include, for example, but is not limited to, an HEMT.

The component 2a may include a diode. The component 2a may include, for example, but is not limited to, a p-n junction diode.

The component 1a may be connected to the component 2a through the elongated portion 1811 and the elongated portion 1812. The component 1a may be electrically connected to the component 2a through the elongated portion 1811 and the elongated portion 1812. The component 1a may be connected to the component 2a through the interconnect structure 181 and the interconnect structure 182. The component 1a may be electrically connected to the component 2a through the interconnect structure 181 and the interconnect structure 182.

The present disclosure relates to the semiconductor devices and the manufacturing methods thereof, and more particularly to a semiconductor device including an HEMT and a diode disposed on opposite sides of the substrate. The present semiconductor device has the advantages of reducing parasitic inductance and parasitic resistance compared to the conventional arts. As a result, the present semiconductor device may improve an operation speed of a switch of the device and reduce the loss of the power. In addition, a reduced volume of the packaged semiconductor device can be obtained, which provides the advantage of better system design and better heat dissipation capability.

As used herein, for ease of description, space-related terms such as “under”, “below”, “lower portion”, “above”, “upper portion”, “lower portion”, “left side”, “right side”, and the like may be used herein to describe a relationship between one component or feature and another component or feature as shown in the figures. In addition to orientations shown in the figures, space-related terms are intended to encompass different orientations of the device in use or operation. A device may be oriented in other ways (rotated 90 degrees or at other orientations), and the space-related descriptors used herein may also be used for explanation accordingly. It should be understood that when a component is “connected” or “coupled” to another component, the component may be directly connected to or coupled to another component, or an intermediate component may exist.

As used herein, terms “approximately”, “basically”, “substantially”, and “about” are used for describing and considering a small variation. When being used in combination with an event or circumstance, the term may refer to a case in which the event or circumstance occurs precisely, and a case in which the event or circumstance occurs approximately. As used herein with respect to a given value or range, the term “about” generally means in the range of ±10%, ±5%, ±1%, or ±0.5% of the given value or range. The range may be indicated herein as from one endpoint to another endpoint or between two endpoints. Unless otherwise specified, all the ranges disclosed in the disclosure include endpoints. The term “substantially coplanar” may refer to two surfaces within a few micrometers (μm) positioned along the same plane, for example, within 10 within 5 within 1 or within 0.5 μm located along the same plane. When reference is made to “substantially” the same numerical value or characteristic, the term may refer to a value within ±10%, ±5%, ±1%, or ±0.5% of the average of the values.

Several embodiments of the disclosure and features of details are briefly described above. The embodiments described in the disclosure may be easily used as a basis for designing or modifying other processes and structures for realizing the same or similar objectives and/or obtaining the same or similar advantages introduced in the embodiments of the disclosure. Such equivalent constructions do not depart from the spirit and scope of the disclosure, and various variations, replacements, and modifications can be made without departing from the spirit and scope of the disclosure.

What is claimed is:

1. A semiconductor device, comprising:
a substrate having a first side and a second side opposite the first side;
a first nitride semiconductor layer disposed on the first side of the substrate;
a second nitride semiconductor layer on the first nitride semiconductor layer and having a band gap greater than a band gap of the first nitride semiconductor layer;
a first electrode disposed on the second nitride semiconductor layer;
a second electrode disposed on the second nitride semiconductor layer;
a first semiconductor structure formed adjacent to the second side of the substrate; and
a second semiconductor structure formed adjacent to the second side of the substrate; and
wherein the first semiconductor structure and the second semiconductor structure are adjacent to each other.

2. The semiconductor device according to claim 1, wherein the first semiconductor structure and the second semiconductor structure form a diode.

3. The semiconductor device according to claim 1, wherein the first semiconductor structure is doped with a first conductive type material.

4. The semiconductor device according to claim 1, wherein the second semiconductor structure is doped with a second conductive type material.

5. The semiconductor device according to claim 1, wherein the second semiconductor structure is undoped.

6. The semiconductor device according to claim 3, wherein the first conductive type material has a concentration approximately from 10¹³ to 10¹⁸ cm⁻³.

7. The semiconductor device according to claim 1, wherein the first semiconductor structure has a depth approximately between 1000 nm and 10000 nm.

8. The semiconductor device according to claim 1, further comprising:
a gate electrode disposed on the second nitride semiconductor layer.

9. The semiconductor device according to claim 1, further comprising:
a passivation layer disposed on the second nitride semiconductor layer and surrounding the first electrode and the second electrode.

10. The semiconductor device according to claim 9, further comprising:
a first interconnect structure passing through the substrate, the first nitride semiconductor layer, the second nitride semiconductor layer, and the passivation layer.

11. The semiconductor device according to claim 10, wherein the first interconnect structure includes a first contact end connected to the first electrode and a second contact end connected to the first semiconductor structure.

12. The semiconductor device according to claim 11, wherein the first interconnect structure includes a first elongated portion connecting the first contact end and the second contact end.

13. The semiconductor device according to claim 1, wherein the substrate has a thickness approximately between 50 μm and 1.5 mm.

14. The semiconductor device according to claim 11, further comprising:
a solder material formed on the first contact end.

15. The semiconductor device according to claim 1, wherein the first electrode is electrically connected to the first semiconductor structure.

16. The semiconductor device according to claim 1, wherein the second electrode is electrically connected to the second semiconductor structure.

17. A method for manufacturing a semiconductor device, comprising:
providing a substrate;
forming a first nitride semiconductor layer on a first side of the substrate;
forming a second nitride semiconductor layer on the first nitride semiconductor layer;
forming a first electrode and a second electrode on the second nitride semiconductor layer; and
forming a first semiconductor structure and a second semiconductor structure at a second side of the substrate, and
wherein the second side is opposite to the first side.

18. The method according to claim 17, further comprising:
doping the first semiconductor structure with a first conductive type material and doping the second semiconductor structure with a second conductive type material.

19. The method according to claim 17, further comprising:
forming a passivation layer on the second nitride semiconductor layer surrounding the first electrode and the second electrode.

20. The method according to claim 19, further comprising:
forming a first via hole by removing a portion of the substrate, the first nitride semiconductor layer, the second nitride semiconductor layer, and the passivation layer; and
forming a first interconnect structure by filling the first via hole.
